(19) United States
(12) Patent Application Publication
(10) Pub. No.: US 2012/0091870 A1
(43) Pub. Date: Apr. 19, 2012

(54) ELECTRONIC DEVICE ENCLOSURE

(75) Inventors: XU-DONG NAN, Shenzhen City (CN); ZHI-PING WU, Shenzhen City (CN)

(73) Assignees: HON HAI PRECISION INDUSTRY CO., LTD., Tu-Cheng (TW); HONG FU JIN PRECISION INDUSTRY (SHENZHEN) CO., LTD., Shenzhen City (CN)

(21) Appl. No.: 13/162,101

(22) Filed: Jun. 16, 2011

(30) Foreign Application Priority Data
Oct. 18, 2010 (CN) 201010510082.6

(51) Int. Cl. H05K 5/02

(52) U.S. Cl. 312/244

(57) ABSTRACT

An electronic device enclosure includes a bracket and a handle. The bracket includes a front plate. A first securing piece extends from the front plate, and three first protrusions are defined in the first securing piece. The handle includes a handhold and a first mounting portion connected to the handhold. A first positioning hole is defined in the first mounting portion. The handle is attached to the first securing piece and rotatable relative to the front plate between a first position and a second position. In the first position, the handhold is substantially parallel to the front plate, and the first positioning hole receives a first one of the three protrusions. In the second position, the handhold is substantially perpendicular to the front plate, and the first positioning hole receives a second one of the three protrusions.

### BACKGROUND

1. Technical Field

The present disclosure relates to electronic device enclosures, more particularly to an electronic device enclosure with a handle.

2. Description of Related Art

In many computer enclosures, a bracket is provided for receiving an electronic component, such as a disk drive or a power supply. However, space in the enclosure may be very limited, making it difficult to install and remove the brackets.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device enclosure in accordance with an embodiment.

FIG. 2 is an assembled view of FIG. 1, showing a handle in a first position.

FIG. 3 is similar to FIG. 2, but showing the handle in a second position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

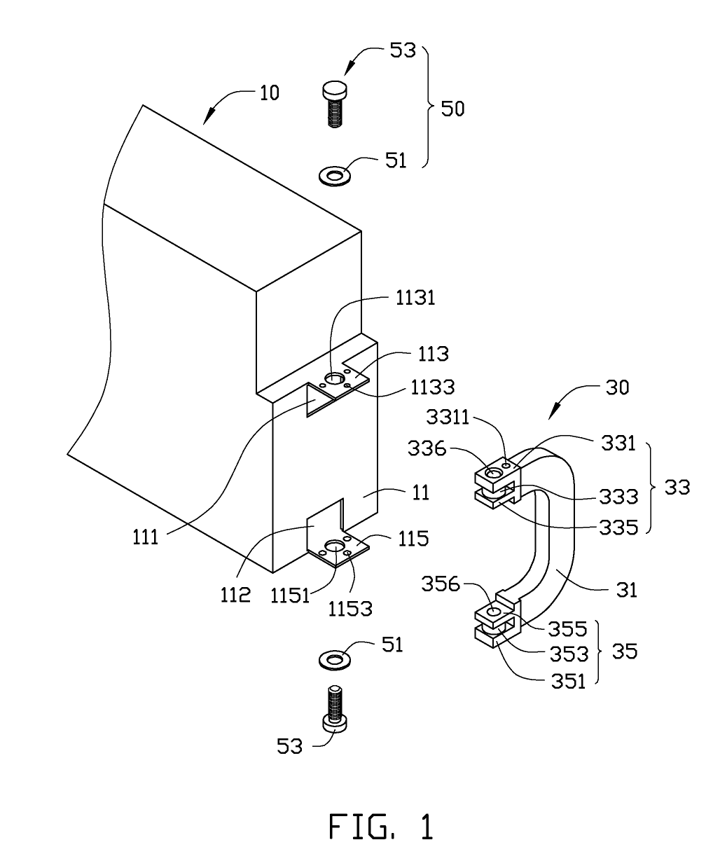

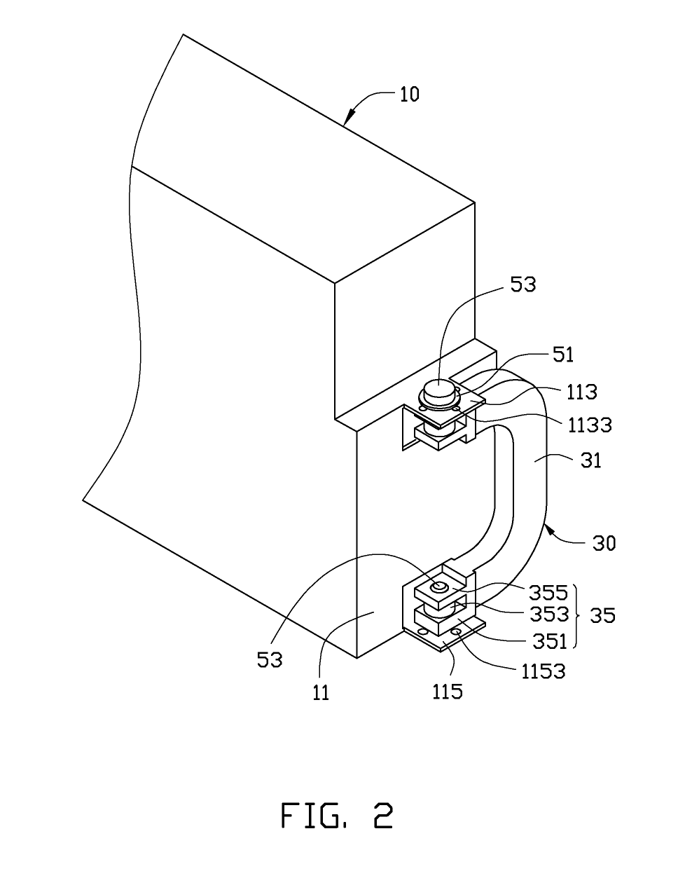

Referring to FIGS. 1 and 2, an electronic device enclosure in accordance with an embodiment includes a bracket 10 (only a portion of the bracket 10 is shown) and a handle 30 attached to the bracket 10. In one embodiment, the bracket 10 can be received in a computer case, and an electronic component, such as a disk drive, can be received in the bracket 10.

The bracket 10 includes a front plate 11 with a first opening 111 and a second opening 112. The first opening 111 and the second opening 112 are arranged in a line. A first securing piece 113, with a first pivot hole 1131, extends from a top edge of the first opening 111. Three first protrusions 1133 are located on a bottom surface of the first securing piece 113. A second securing piece 115 extends from a bottom edge of the second opening 112. The second securing piece 115 defines a second pivot hole 1151 aligned with the first pivot hole 1131. Three second protrusions 1153 are located on a top surface of the second securing piece 115. In one embodiment, the first securing piece 113 is substantially parallel to the second securing piece 115 and perpendicular to the front plate 11. In one embodiment, the three first protrusions 1133 surround the first pivot hole 1131 and are arranged at corners of a first isosceles triangle, and the three second protrusions 1153 surround the second pivot hole 1151 and are arranged at corners of a second isosceles triangle.

The handle 30 includes a handhold 31, a first mounting portion 33 connected to a first end of the handhold 31, and a second mounting portion 35 connected to a second end of the handhold 31. In one embodiment, the first mounting portion 33 is substantially parallel to the second mounting portion 35. The first mounting portion 33 includes a first top piece 331, a first bottom piece 335, and a first post 333 located between the first top piece 331 and the first bottom piece 335.

The first top piece 331 defines a first positioning hole 3311 that correspond to the three first protrusions 1133. A first through hole 336 is defined in the first post 333 through the first top piece 331 and the first bottom piece 335. The second mounting portion 35 has substantially the same configuration as the first mounting portion 33 and includes a second bottom piece 351, a second post 353, and a second top piece 355. The second bottom piece 351 has a second positioning hole (not shown), corresponding to the three second protrusions 1153. The second post 353 has a second through hole 356, and the through hole 356 extends through the second top piece 355 and the second bottom piece 351. In one embodiment, the handhold 31 is U-shaped, and the first mounting portion 33 is substantially parallel to the second mounting portion 35.

Two fixing members 50 are provided for securing the handle 30 to the bracket 10. Each fixing member 50 includes a screw 53 and a washer 51.

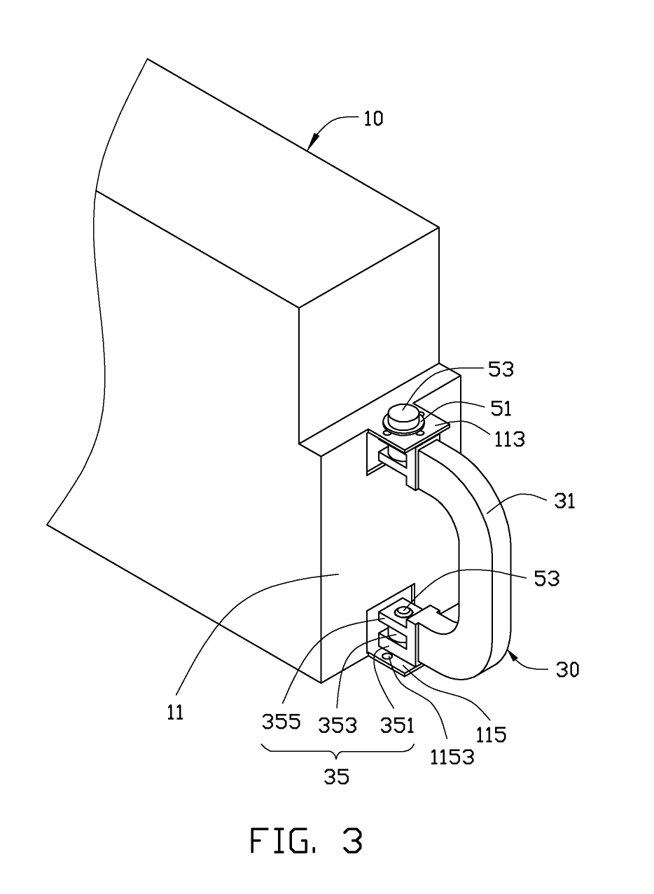

Referring to FIGS. 2-3, in assembly, the handle 30 is located between the first securing piece 113 and the second securing piece 115. The first securing piece 113 abuts on a top surface of the first top piece 331, and the first through hole 336 is aligned with the first pivot hole 1131. The washer 51 is attached to the 53, and the screw 53 is engaged in the first through hole 336 and the first pivot hole 1131, to secure the first mounting portion 33 to the first securing piece 113. In one embodiment, the second mounting portion 35 can be secured to the second securing piece 115 by the same means as the first mounting portion 33. The three first protrusions 1133 abut a top surface of the first top piece 331, and the three second protrusions 1153 abut a bottom surface of the second bottom piece 351.

The handle 30 is rotatable relative to the front plate 11 between a first position (see FIG. 2) and a second position (see FIG. 3). In the first position, the handhold 31 is substantially parallel to the front plate 11, and the first positioning hole 3311 of the handle 30 receives a first one of the three protrusions 1133, that is adjacent to the front plate 11. In the second position, the handhold 31 is substantially parallel to the front plate 11, and the first positioning hole 3311 receives a second one of the three protrusions 1133. A distance between the front plate 11 and the second one of the three protrusions 1133 is farther than that between the front plate 11 and the second one of the three protrusions 1133.

When the bracket 10 is received in the computer case, the handle 30 is rotated to the first position, so that the handle 30 occupies little space. To take the bracket 10 out of the computer case, the handle 30 is rotated to the second position, and the bracket 10 can be taken out from the computer case.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure comprising:
a bracket comprising a front plate, a first securing piece extending from the front plate, and three first protrusions located on the first securing piece; and
a handle comprising a handhold and a first mounting portion connected to the handhold; and a first positioning hole defined in the first mounting portion;
wherein the handle is attached to the first securing piece and rotatable relative to the front plate between a first position and a second position, in the first position, the handhold is substantially parallel to the front plate, and the first positioning hole receives a first one of the three protrusions; in the second position, the handhold is substantially perpendicular to the front plate, and the first positioning hole receives a second one of the three protrusions.

2. The electronic device enclosure of claim 1, wherein the first securing piece is substantially perpendicular to the front plate.

3. The electronic device enclosure of claim 1, wherein the three protrusions are arranged at three corner of a triangle.

4. The electronic device enclosure of claim 1, wherein the first mounting portion comprises a first top piece, and the first securing piece is attached to a top surface of the first top piece.

5. The electronic device enclosure of claim 4, wherein the first mounting portion further comprises a first bottom piece, and the first bottom piece is substantially parallel to the first top piece.

6. The electronic device enclosure of claim 5, wherein the first mounting portion further comprises a first post located between the first top piece and the first bottom piece;
and a though hole is defined in the first post through the first top piece and the first bottom piece.

7. The electronic device enclosure of claim 1, wherein a first opening is defined in the front plate, and the first securing piece extends from an edge of the first opening.

8. The electronic device enclosure of claim 1, wherein the handhold is U-shaped.

9. An electronic device enclosure comprising:
a bracket comprising a front plate; a first securing piece and a second securing piece extending from the front plate; three first protrusions defined in the first securing piece, and three first protrusions located on in the second securing piece; and
a handle comprising a first mounting portion, a second mounting portion and a handhold located between the first mounting portion and the second mounting portion ; a first positioning hole defined in the first mounting portion, and a second positioning hole defined in the second mounting portion;
wherein the handle is rotatable and located between the first securing piece and the second securing piece, the first positioning hole receives one of the three first protrusions, and the second positioning hole receives one of the three protrusions.

10. The electronic device enclosure of claim 9, wherein the handle is rotatable relative to the front plate between a first position, where the handhold is substantially parallel to the front plate, and a second position, where the handhold is substantially perpendicular to the front plate.

11. The electronic device enclosure of claim 9, wherein the first securing piece is substantially perpendicular to the front plate.

12. The electronic device enclosure of claim 9, wherein the first securing piece is substantially parallel to the second securing piece.

13. The electronic device enclosure of claim 9, wherein the three protrusions are arranged at three corner of a triangle.

14. The electronic device enclosure of claim 9, wherein the first mounting portion comprises a first top piece, and the first securing piece is attached to a top surface of the first top piece.

15. The electronic device enclosure of claim 14, wherein the first mounting portion further comprises a first bottom piece, and the first bottom piece is substantially parallel to the first top piece.

16. The electronic device enclosure of claim 15, wherein the first mounting portion further comprises a first post located between the first top piece and the first bottom piece;
and a though hole, extending through the first top piece and the first bottom piece, is defined in the first post.

17. The electronic device enclosure of claim 9, wherein a first opening is defined in the front plate, and the first securing piece extends from an edge of the first opening.

18. The electronic device enclosure of claim 9, wherein the handhold is U-shaped.
